(19) United States
(12) Patent Application Publication
(10) Pub. No.: US 2011/0133849 A1
(43) Pub. Date: Jun. 9, 2011

(54) LOW PHASE NOISE VOLTAGE-CONTROLLED OSCILLATOR (VCO) USING HIGH QUALITY FACTOR METAMATERIAL TRANSMISSION LINES

(75) Inventors: Jae-Won Choi, Seoul (KR); Chul-Hun Seo, Seoul (KR); Young-Jun Chong, Daejeon-si (KR); Jae-Ick Choi, Daejeon-si (KR)

(73) Assignees: Soongsil University Research Consortium Techno-PARK, Seoul (KR); Electronics and Telecommunications Research Institute, Daejeon-si (KR)

(21) Appl. No.: 12/795,085

(22) Filed: Jun. 7, 2010

(30) Foreign Application Priority Data
Dec. 8, 2009 (KR) 10-2009-0121368

(51) Int. Cl. H03B 5/18

(52) U.S. Cl. 331/187

(57) ABSTRACT

A voltage-controlled oscillator (VCO), specifically, a low phase noise VCO using metamaterial transmission lines including a signal plane on which transmission lines are etched in an interdigital fashion is provided. Though high quality resonators based on a metamaterial structure, improvement of the phase noise of the VCO and circuit miniaturization are achieved.

### CROSS-REFERENCE TO RELATED APPLICATION

This application claims the benefit under 35 U.S.C. §119(a) of a Korean Patent Application No. 10-2009-0121368, filed on Dec. 8, 2009, the entire disclosure of which is incorporated herein by reference for all purposes.

### BACKGROUND

1. Field

The following description relates to a voltage-controlled oscillator (VCO), and more particularly, to a low phase noise voltage-controlled oscillator (VCO) using high quality factor interdigital metamaterial transmission lines (TLs) based on complementary spiral resonators (CSR).

2. Description of the Related Art

An oscillator is an energy conversion circuit to convert direct-current power into alternating-current power, and most oscillators for ultrahigh frequency developed up to now implement such power conversion using FET or BJT active devices. The FET or BJT active devices act to provide negative resistance which is an oscillation condition. A part having negative resistance is coupled to a resonator and is connected to a load resistor of a transistor and an external feedback circuit. The oscillator oscillates at a resonance frequency of the resonator when meeting the oscillation condition, thus transferring alternating-current power to the load resistor.

The oscillation frequency of the oscillator is dependent on the resonance frequency of the resonator. That is, the oscillation frequency of the oscillator varies depending on the resonance frequency of the resonator. This is a concept of a voltage-controlled oscillator (VCO).

The resonator may be a LC resonator, a dielectric resonator, a Yitterium Iron Garnet or the like.

An LC resonator is mainly used in a device not needing a wide frequency band since it can be easily manufactured at low cost and has a compact size. The LC resonator, which is composed of an inductor and a capacitor, changes its resonance frequency using a variable capacitor. The bandwidth of an oscillator depends on a variable frequency band of a resonator. The variable capacitor may be a varactor diode which increases the length of its space charge layer by increasing direct-current reverse bias and which induces changes in capacitance due to the increase in length of the space charge layer.

The VCO represents electronic vibrations as voltage variations and is an oscillator circuit which can vary an output frequency by adjusting an input voltage. In detail, the VCO changes an output frequency by adjusting a FET DC bias voltage or generating a separate control voltage.

The VCO may be implemented as a variable frequency oscillation circuit module to oscillate, transfer and receive frequencies of a mobile phone using a voltage applied from a synthesizer. In order to use the VCO in a mobile communication device, demands for further miniaturization and weight reduction of the VCO are increasing together demands allowing low current consumption and low-voltage operation.

### SUMMARY

The following description relates to the improvement of phase noise properties and circuit miniaturization of a voltage-controlled oscillator (VCO) through high quality resonators based on a metamaterial structure.

Also, the following description relates to a low phase noise VCO using high Q factor interdigital metamaterial transmission lines (TLs) based on complementary spiral resonators (CSRs).

In one general aspect, there is provided a low phase noise voltage-controlled oscillator (VCO) having a high quality factor metamaterial transmission line, including: a ground plane on which complementary spiral resonators (CSRs) are etched; and a signal plane on which transmission lines are etched in an interdigital fashion.

The CSRs etched on the ground plane are arranged as unit cell-pairs in series, each unit cell-pair consisting of two unit cells positioned in parallel.

The CSRs etched on the ground plane are arranged as six unit cell-pairs, each unit cell-pair consisting of two unit cells positioned in parallel, wherein each unit cell has a three-turn topology.

A current flowing through each unit cell of a unit cell-pair consisting of two unit cells positioned in parallel flows in one direction in a horizontal direction of CSRs of the unit cell, and flows in the opposite direction in a vertical direction of the CSRs of the unit cell.

A width of the unit cell-pair is identical to a width of a transmission line etched in the interdigital fashion.

The transmission lines etched in the interdigital fashion on the signal plane are arranged in series between the unit cell-pairs arranged in series on the ground plane.

The low phase noise VCO is implemented using a high quality factor interdigital metamaterial TL based on complementary spiral resonators (CSR) for improving phase-noise.

The low phase noise VCO improves phase-noise and achieves circuit miniaturization through the high quality factor metamaterial TL based on resonators.

Other features and aspects will be apparent from the following detailed description, the drawings, and the claims.

### BRIEF DESCRIPTION OF THE DRAWINGS

FIG. 1 is a diagram illustrating an example of a structure in which spiral resonators are etched on the ground plane and transmission lines are etched in an interdigital fashion on the signal plane.

FIG. 2 illustrates four cases where current passing through spiral resonators has different directions.

FIG. 3 shows the simulation results of resonance quality factor (Q) properties with respect to the width (w) between a pair of unit cells connected in parallel in the four cases of the different current directions illustrated in FIG. 2.

FIG. 4 shows the simulation results of resonance Q properties with respect to the line thickness (t) of a unit cell of complementary spiral resonators (CSRs) and the separation (s) between the lines of the unit cell.

FIG. 5 shows the simulation results of resonance Q properties in accordance to the number of unit cell-pairs.

FIGS. 6A and 6B respectively illustrate examples where no interdigital structure is etched on the signal plane and where an interdigital structure is etched on the signal plane.

FIG. 7 shows the simulation results of resonance Q properties with respect to the width (w) between CSRs etched on the ground plane in accordance to the width (d) of a transmission line, when transmission lines have no interdigital structure on the signal plane in the structure illustrated in FIG. 1.

FIG. 8 shows the simulation results of resonance Q properties with respect to the width (w) of CSRs etched on the ground plane when an interdigital structure exists on a transmission line forming the signal plane and when no interdigital structure exists on the transmission line, according to an example.

FIG. 9A illustrates a signal plane of metamaterial transmission lines without an interdigital structure based on CSRs.

FIG. 9B illustrates a ground plane of the metamaterial transmission lines without the interdigital structure based on the CSRs.

FIG. 9C illustrates an example of a signal plane of metamaterial transmission lines based on the CSRs, on which the interdigital structure is etched.

FIG. 9D illustrates an example of a ground plane of the metamaterial transmission lines based on the CSRs, on which the interdigital structure is etched.

FIG. 10 shows the simulation results and measurements of resonance Q properties of the metamaterial transmission lines illustrated in FIGS. 9A and 9B.

FIG. 11 shows the simulation results and measurements of resonance Q properties of the metamaterial transmission lines illustrated in FIGS. 9C and 9D.

FIG. 12 illustrates a layout of a low phase noise voltage-controlled oscillator (VCO) using the interdigital metamaterial transmission lines based on the CSRs.

FIG. 13 shows an output spectrum example of a VCO using the interdigital metamaterial transmission lines based on the CSRs.

FIG. 14 shows phase-noise properties of a VCO using the interdigital metamaterial transmission lines based on the CSRs.

FIG. 15 shows the simulation results and measurements of phase-noise properties when an interdigital structure is etched on the signal plane and when no interdigital structure is etched on the signal plane.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

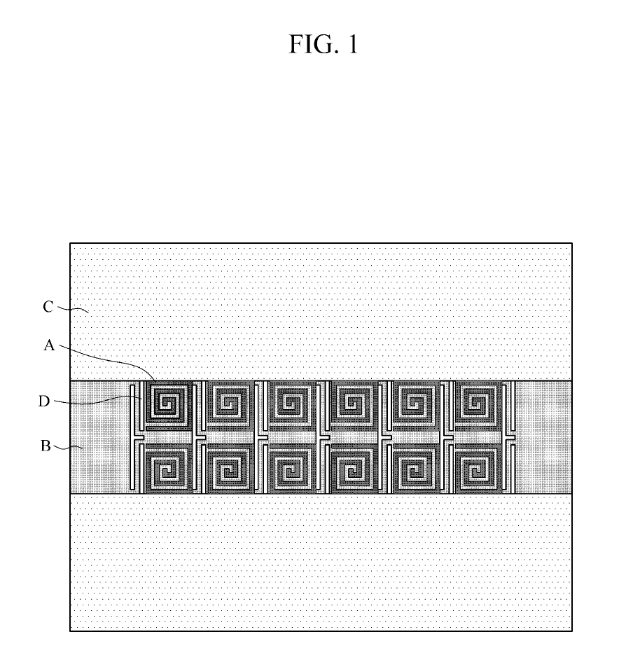

FIG. 1 is a diagram illustrating an example of a structure in which complementary spiral resonators (CSRs) are etched on the ground plane and transmission lines are etched in an interdigital fashion on the signal plane.

In FIG. 1, A regions represent the CSRs etched on the ground plane, B regions represent the transmission lines etched in the interdigital fashion on the signal plane, C regions represent the ground plane and D regions represent the etched parts of the interdigital transmission lines.

Each unit cell of the CSRs etched on the ground plane has a three-turn topology and two unit cells arranged in parallel form a unit cell-pair. In addition, six unit cell-pairs are aligned in series.

The three-turn unit cell is used is because the resonance quality factor value becomes saturated at four-turns or higher and increasing the number of turns increases only the cell size without producing any further improvement of the resonance Q value.

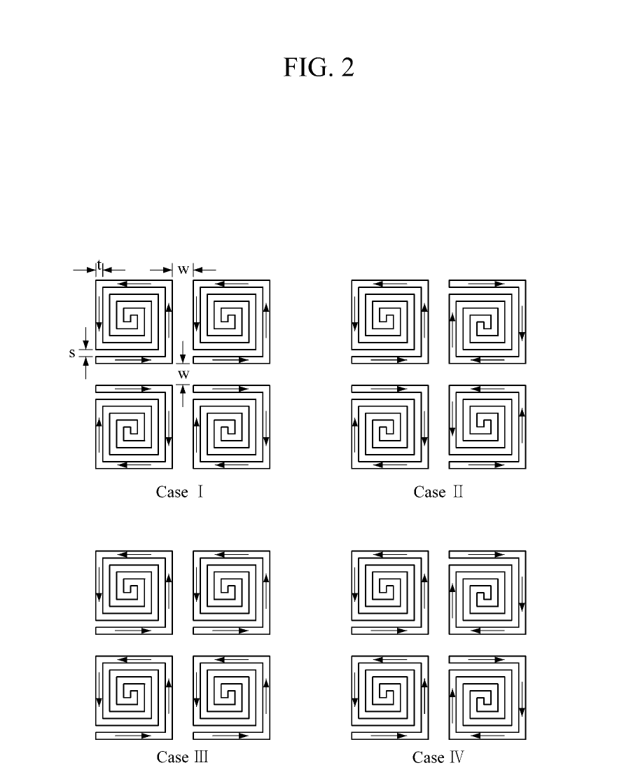

FIG. 2 illustrates four cases where current passing through spiral resonators has different directions.

Referring to FIG. 2, the directions of current passing through the spiral resonators may be classified into four different directions: the horizontal current direction of each spiral resonator is the same as that of its adjacent spiral resonators and the vertical current direction is opposite to that of the adjacent spiral resonators (Case I); the horizontal and vertical current directions of each spiral resonator are the same as those of the adjacent spiral resonators (Case II), the horizontal and vertical current directions of each spiral resonator are respectively opposite to those of the adjacent spiral resonators (Case III), and the horizontal current direction of each spiral resonator is opposite to that of the adjacent spiral resonators and the vertical current direction is the same as that of the adjacent spiral resonators (Case IV).

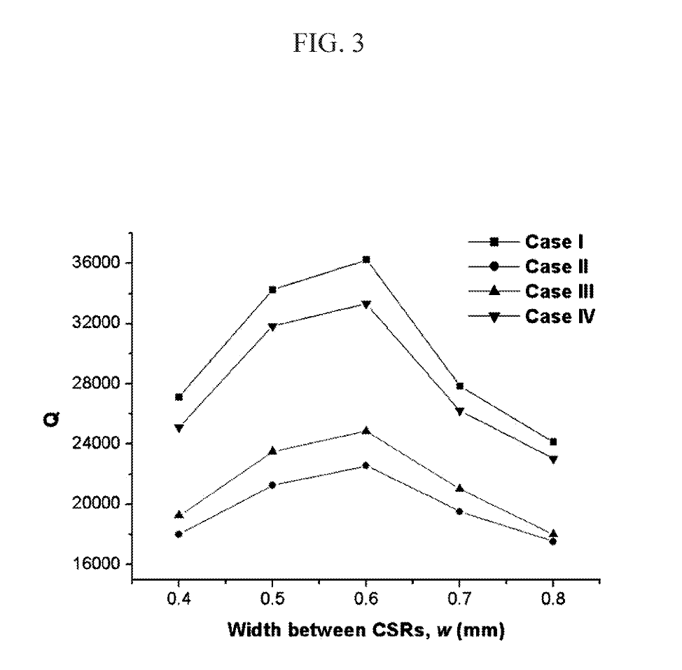

FIG. 3 shows the simulation results of resonance quality factor properties with respect to the width (w) between a pair of unit cells connected in parallel in the four cases of the different current directions illustrated in FIG. 2.

FIG. 3 shows resonance Q properties when the number of unit cell-pairs, each unit cell-pair consisting of two unit cells arranged in parallel, is two. As depicted in FIG. 3, when the width w between each unit cell-pair is 0.6 mm, the resonance Q value is the best in Case I having the same horizontal current direction and opposite vertical current directions.

From the simulation results, it can be seen that the resonance Q value can be improved by designing CSRs such that the horizontal current direction of each spiral resonator is the same as that of its adjacent spiral resonators and the vertical current direction is opposite to that of the adjacent spiral resonators

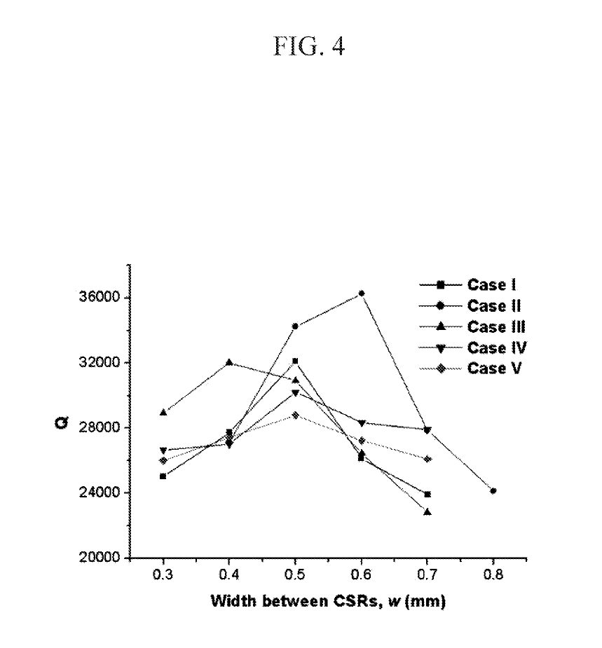

FIG. 4 shows the simulation results of the resonance Q properties with respect to the line thickness (t) of a unit cell of CSRs and the separation (s) between the lines of the unit cell.

FIG. 4 is a graph showing resonance Q properties with respect to the width w of a unit cell-pair consisting of two unit cells positioned in parallel in five cases: where t=s=0.1 mm (Case I), t=s=0.2 mm (Case II), t=0.2 mm and s=0.3 mm (Case III), t=0.3 mm and s=0.2 mm (Case IV) and t=s=0.3 mm (Case V).

In the graph of FIG. 4, the number of unit cell-pairs is two and the current directions between CSRs are set to have the same horizontal current direction and opposite vertical current directions. As seen from FIG. 4, the resonance Q value is the best in Case II when the width w of a unit cell-pair is 0.6 mm and t=s=0.2 mm.

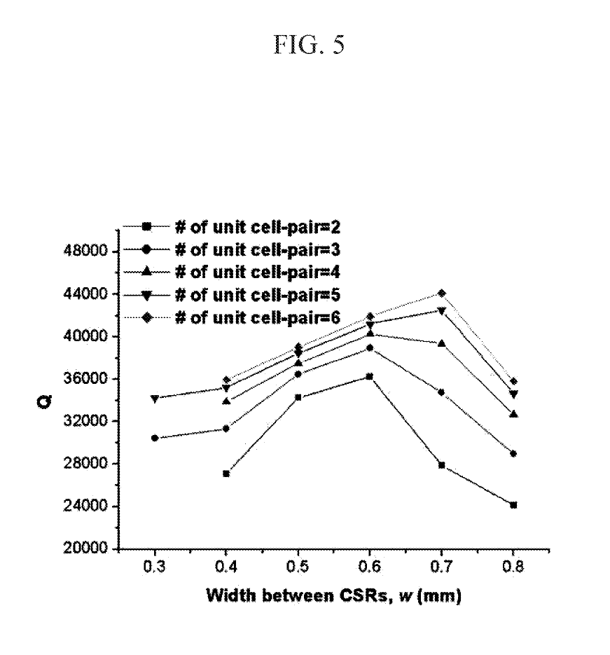

FIG. 5 is a graph showing the simulation results of resonance Q properties in accordance to the number of unit cell-pairs.

In the graph of FIG. 5, the current directions between CSRs are set to have the same horizontal current direction and opposite vertical current directions, and the line thickness t of a unit cell and the separation s between the lines of the unit cell are all 0.2 mm. It can be seen from FIG. 5 that the resonance Q value is the most excellent when 6 unit cell-pairs are arranged with the width of 0.7 mm between the unit cell-pairs.

Also, it can be seen from the simulation results depicted in FIGS. 3, 4 and 5 that the resonance Q value can be improved by designing an oscillator in which three-turn CSRs are utilized, the current directions between the CSRs are set to have the same horizontal current direction and opposite vertical current directions, the line thickness t of each unit cell and the separation s between the lines of the unit cell are all 0.2 mm, the width w of unit cell-pairs is 0.7 mm and the number of the unit cell-pairs is six where each unit cell-pair consisting of two unit cells positioned in parallel.

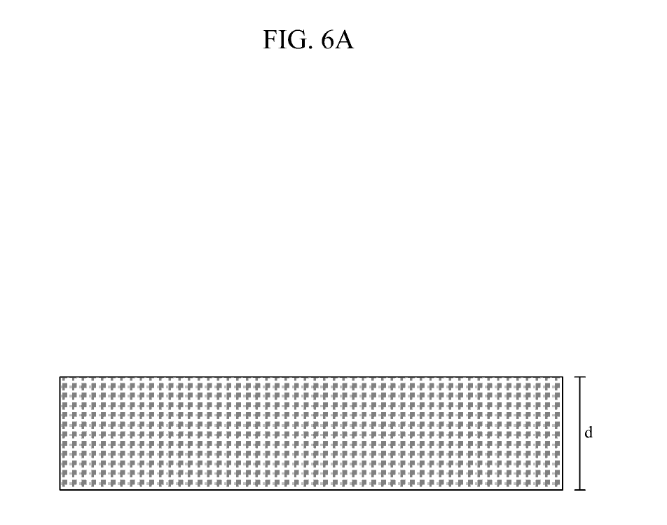

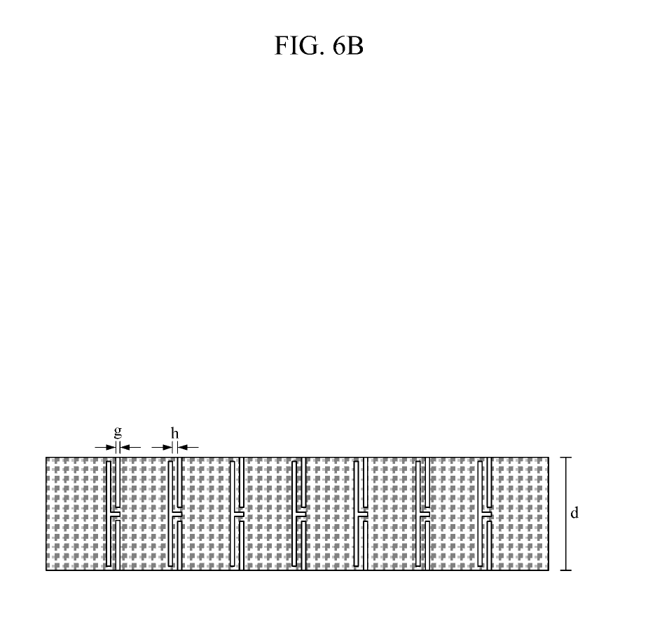

FIGS. 6A and 6B respectively illustrate examples where no interdigital structure is etched on the signal plane and where an interdigital structure is etched on the signal plane.

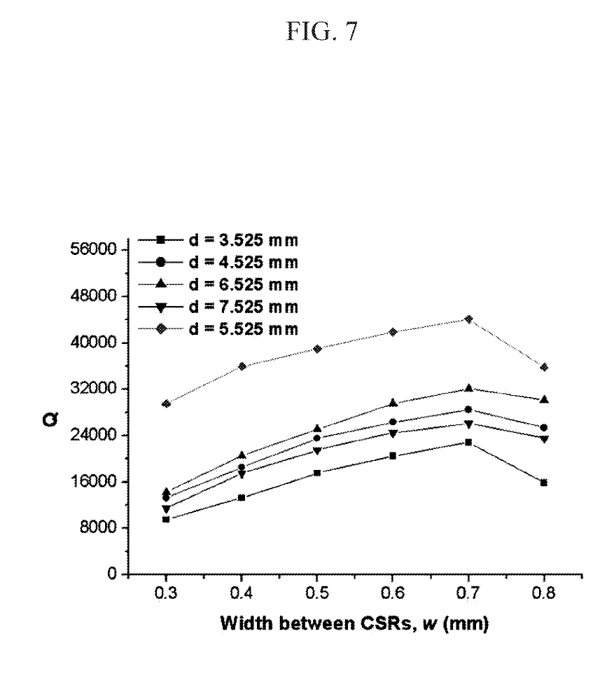

FIG. 6A illustrates transmission lines where no interdigital structure is etched on the signal plane. FIG. 7 shows the simulation results of resonance Q properties with respect to the width (w) between CSRs etched on the ground plane in accordance to the width (d) of a transmission line, when transmission lines have no interdigital structure on the signal plane in the structure illustrated in FIG. 1.

It can be seen from FIG. 7 that the resonance Q value is the best when the width d of the transmission line is 5.525 mm that is the same as the width w between a unit cell-pair of CSRs forming the ground plane, unit cells of each pair positioned in parallel, and the width w between the CSRs is 0.7 mm.

This is because the coupling characteristic between the CSRs forming the ground plane and the transmission lines forming the signal plane becomes a maximum when the width between a unit cell-pair of the CSRs is the same as the width of the transmission line. If the width of each transmission line of the signal plane is greater or less than the width between the unit cell-pair of the CSRs, the coupling characteristic therebetween deteriorates.

FIG. 6B illustrates an example where transmission lines are etched in an interdigital fashion on the signal plane. Referring to FIG. 6B, the width of each etched line is denoted as g and the width between the etched lines is denoted as h. White areas of FIG. 6B correspond to the etched lines.

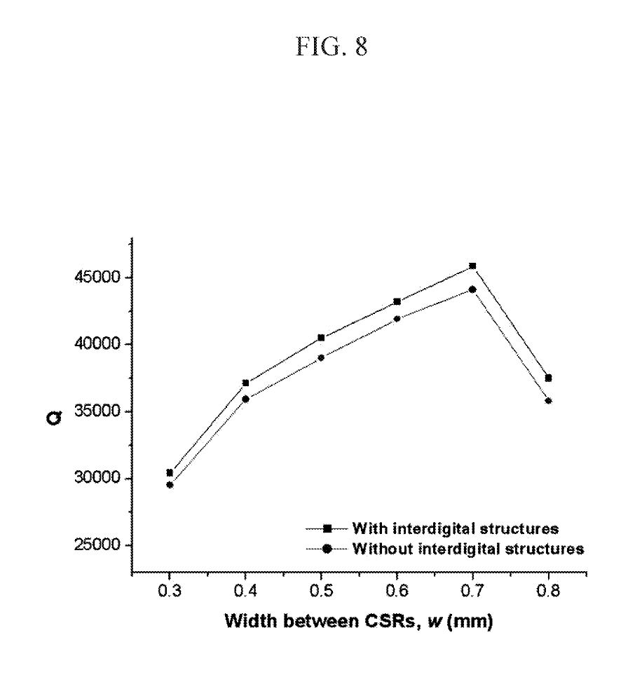

FIG. 8 shows the simulation results of resonance Q properties with respect to the width (w) of CSRs etched on the ground plane when an interdigital structure exists on transmission lines forming the signal plane and when no interdigital structure exists on the transmission lines.

It can be seen from FIG. 8 that the transmission lines on which the interdigital structure is etched exhibit a more excellent resonance Q value than the transmission lines on which no interdigital structure is etched. Further, it can be seen from FIG. 8 that the resonance Q value is best when the width between CSRs etched on the ground plane is 0.7 mm, wherein the width g of each etched line of the interdigital structure is 0.23 mm and the width h of the etched lines is 0.24 mm.

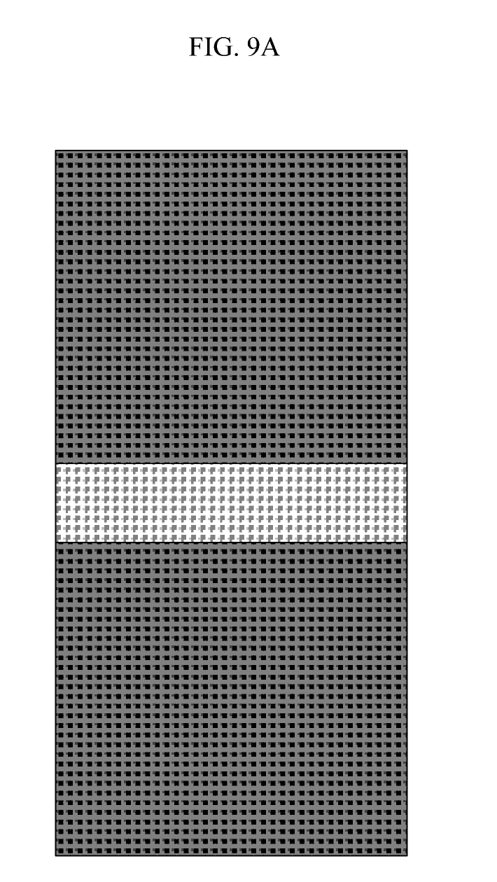

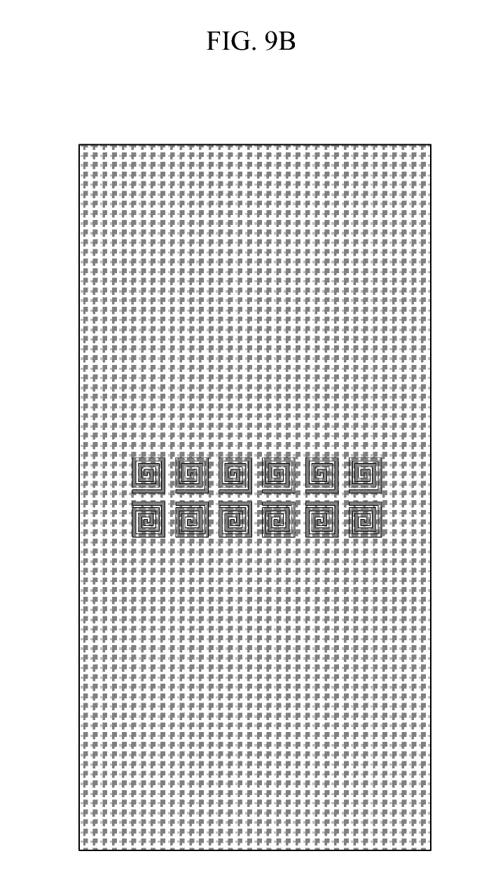

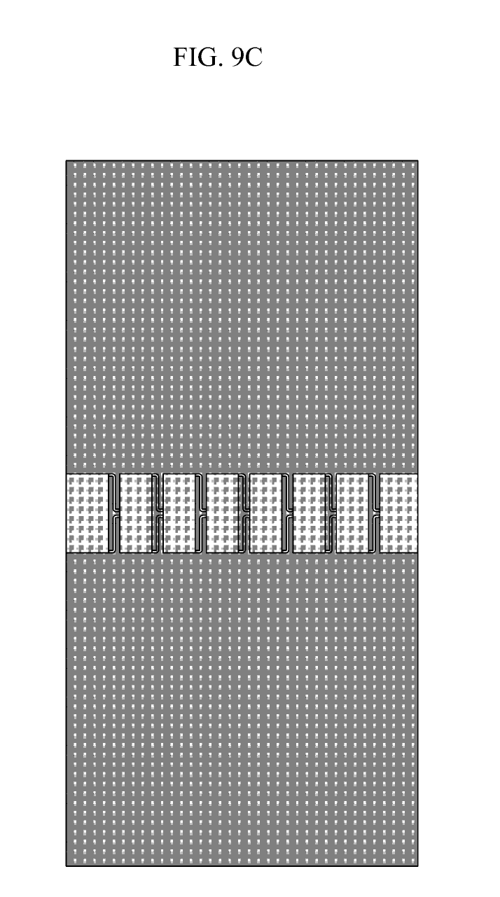

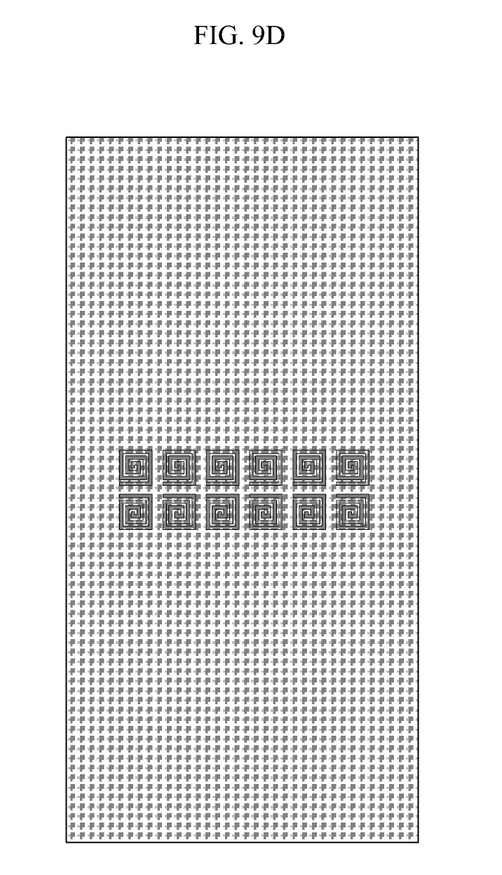

FIG. 9A illustrates the signal plane of metamaterial transmission lines without an interdigital structure based on CSRs.

FIG. 9B illustrates the ground plane of the metamaterial transmission lines without the interdigital structure based on the CSRs.

FIG. 9C illustrates the signal plane of metamaterial transmission lines based on CSRs, on which the interdigital structure is etched.

FIG. 9D illustrates the ground plane of the metamaterial transmission lines based on the CSRs, on which the interdigital structure is etched.

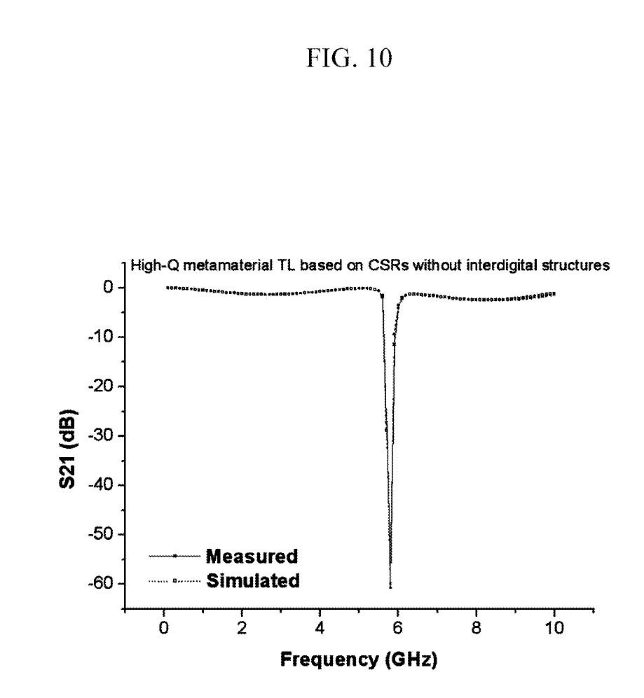

FIG. 10 shows the simulation results and measurements of resonance Q properties of the metamaterial transmission lines illustrated in FIGS. 9A and 9B.

The resonance Q value of the metamaterial transmission lines without the interdigital structure based on the CSRs provides a S21 measurement of −59.85 dB at a resonance frequency of 5.8 GHz. In this case, a Q value measurement is 44100. As seen from FIG. 10, the simulation results are similar to the actual measurements.

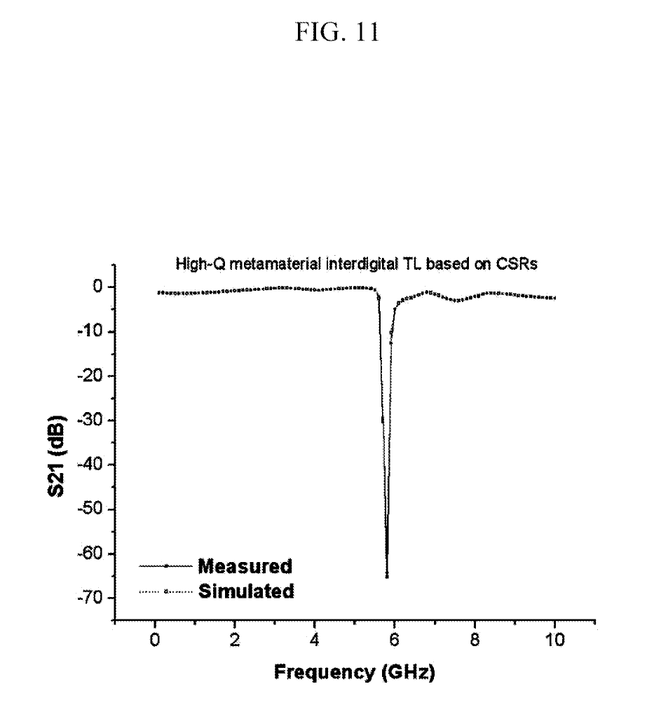

FIG. 11 shows the simulation results and measurements of resonance Q properties of the metamaterial transmission lines illustrated in FIGS. 9C and 9D.

The resonance Q value of the metamaterial transmission lines without the interdigital structure based on the CSRs provides a S21 measurement of −65.17 dB at a resonance frequency of 5.8 GHz. In this case, a Q value measurement is 45800. As seen from FIG. 11, the simulation results are similar to the actual measurements.

Comparing FIG. 10 to FIG. 11, it will be understood that a high resonance Q value can be obtained due to the coupling effect of the complementary spiral resonators etched on the ground plane and the interdigital transmission lines designed on the signal plane, and the inter-coupling effect between the ground plane and the signal plane.

Also, it will be understood that the interdigital transmission lines have a more excellent resonance Q value than the transmission lines without the interdigital structure. In addition, the excellent resonance Q value of the interdigital transmission lines increases capacitance and inductance, which leads to miniaturization of a resonator under the same resonance frequency conditions.

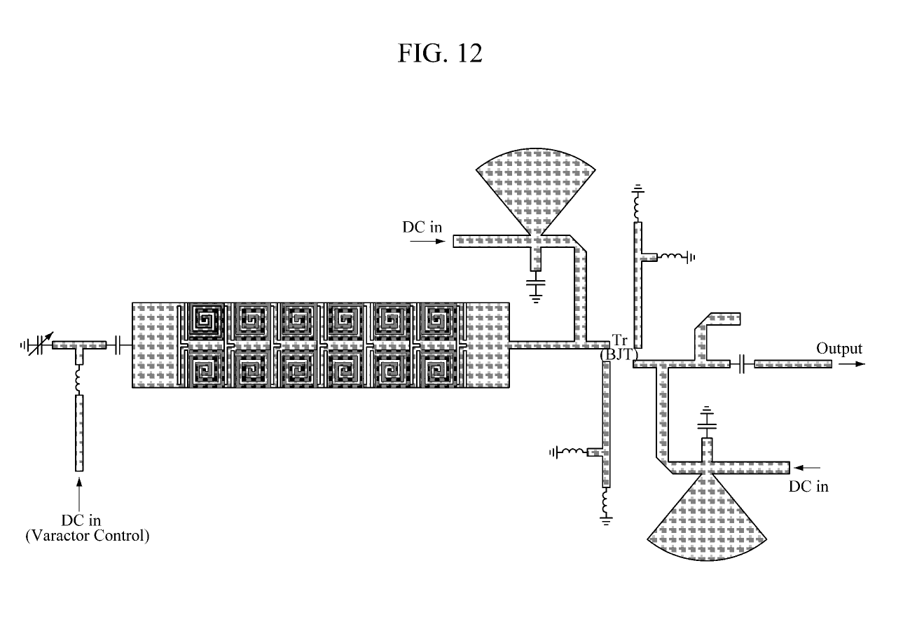

FIG. 12 illustrates a layout example of a low phase noise voltage-controlled oscillator (VCO) using the interdigital metamaterial transmission lines based on the CSRs.

The VCO uses a BJT transistor as an active device and uses a varactor diode to adjust an oscillating frequency. The interdigital metamaterial transmission lines based on the CSRs connect to the base terminal of the BJT transistor, and the varactor diode for adjusting the oscillating frequency connects to one end of the CSR part.

Negative resistors connect symmetrically to the emitter terminal of the BJT transistor in order to reduce phase noise. An output matching circuit connects to the collector terminal of the BJT transistor. A bias circuit utilizes a radial stub to apply a voltage to the VCO.

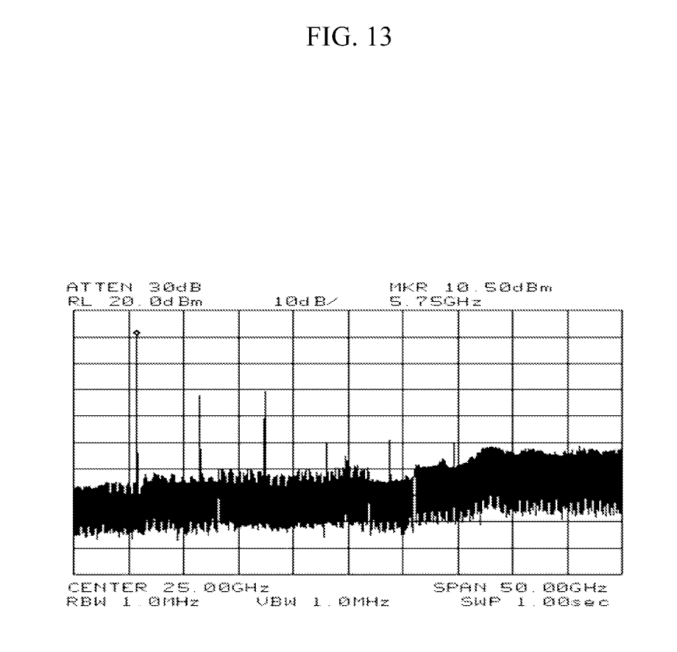

FIG. 13 shows an output spectrum example of a VCO using the interdigital metamaterial transmission lines based on the CSRs.

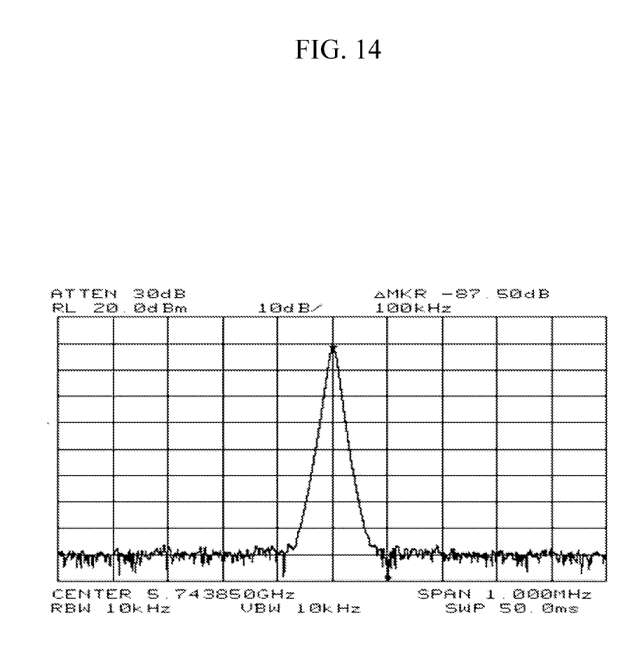

Referring to FIG. 14, the output power of the VCO is 10.5 dBm and its harmonics characteristic is −22.17 dBc.

FIG. 14 shows phase-noise properties of the VCO using the interdigital metamaterial transmission lines based on the CSRs.

Referring to FIG. 14, the phase noise of the VCO is from −127.50 to 124.87 dBc/Hz at an offset frequency 100 kHz, wherein a frequency tuning range is from 5.744 to 5.86 GHz.

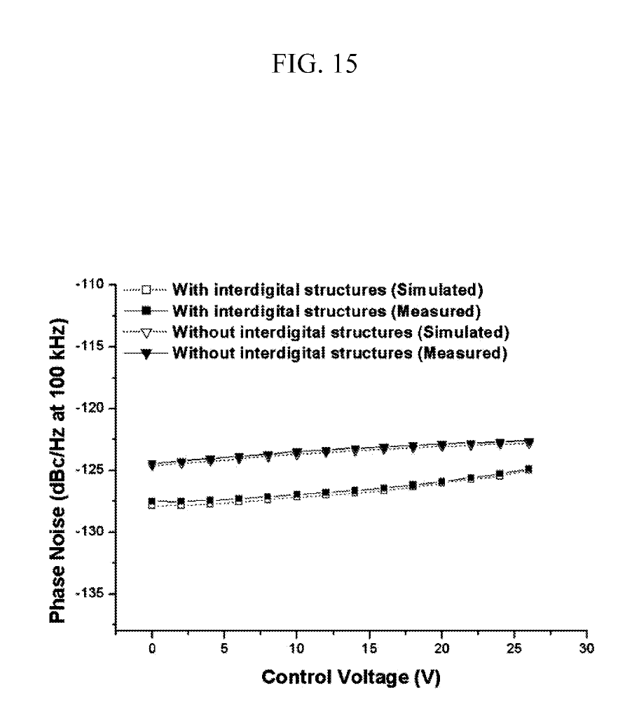

FIG. 15 shows the simulation results and measurements for phase-noise properties when the interdigital structure is etched on the signal plane and when no interdigital structure is etched on the signal plane.

Referring to FIG. 15, the measurements are similar to the simulation results, and when a voltage range applied to the varator diode to tune the oscillating frequency of the VCO is from 0 to 26, the phase-noise of the VCO using the interdigital metamaterial transmission lines is improved by about 3.06 dB over that of a VCO using the metamaterial transmission lines without the interdigital structure.

$$F O M = L \{ Δ f \} - 20 log ( \frac{{f}_{0}}{Δ f} ) + 10 log ( \frac{P}{1 mW} ) \qquad ( 1 )$$

In Equation 1, FOM (Figure-Of-Merit) is a performance index for comparing the operation features of VCOs implemented using different methods, which is expressed in dB, L{Δf} represents a phase-noise at a local point spaced an offset frequency Δf from a center frequency f0 and P represents the amount of power that is consumed in a VCO core. The FOM of the VCO according to the current example is from −207.17 to −205.67 dBc/Hz at a frequency tuning range from 5.744 to 5.86 GHz.

| | | VCO using high-Q | |
|---|---|---|---|
| | | metamaterial TL | VCO using high-Q |
| | | based on CSRs | metamaterial |
| | | without interdigital | interdigital TL based |
| Parameters | Unit | structure | on CSRs |
| Oscillation | GHz | 5.73 | 5.744 |
| Frequency | | | |
| Output Power | dBm | 10.17 | 10.50 |
| Harmonics | dBc | −21.84 | −22.17 |
| Phase Noise | dBc/Hz | −124.43 | −127.50 |
| (100 kHz)* | | | |
| Tuning Range | MHz | 120 | 116 |
| FOM | dBc/Hz | −204.28 | −207.17 |

The above table shows the comparison results of the operation measurements of the VCO using the metamaterial transmission lines without the interdigital structure based on the CSRs and the VCO using the interdigital metamaterial transmission lines based on the CSRs. It can be seen from FIG. 16 that the performance of the VCO has been improved as well as the improvements to phase-noise.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A low phase noise voltage-controlled oscillator (VCO) having a high quality factor metamaterial transmission line, comprising:
a ground plane on which complementary spiral resonators (CSRs) are etched; and
a signal plane on which transmission lines are etched in an interdigital fashion.

2. The low phase noise VCO of claim 1, wherein the CSRs etched on the ground plane are arranged as unit cell-pairs in series, each unit cell-pair consisting of two unit cells positioned in parallel.

3. The low phase noise VCO of claim 1, wherein the CSRs etched on the ground plane are arranged as six unit cell-pairs, each unit cell-pair consisting of two unit cells positioned in parallel, wherein each unit cell has a three-turn topology.

4. The low phase noise VCO of claim 2, wherein a current flowing through each unit cell of a unit cell-pair consisting of two unit cells positioned in parallel flows in one direction in a horizontal direction of CSRs of the unit cell, and flows in the opposite direction in a vertical direction of the CSRs of the unit cell.

5. The low phase noise VCO of claim 2, wherein a width of the unit cell-pair is identical to a width of a transmission line etched in the interdigital fashion.

6. The low phase noise VCO of claim 2, wherein the transmission lines etched in the interdigital fashion on the signal plane are arranged in series between the unit cell-pairs arranged in series on the ground plane.

7. The low phase noise VCO of claim 2, wherein a line thickness t of the unit cell is 0.2 mm, a separation s between lines of the unit cell is 0.2 mm and a width w between two neighboring unit cells is 0.6 mm or 0.7 mm

8. The low phase noise VCO of claim 2, wherein a width g of an etched part of each transmission line is 0.23 mm and a width h between etched parts of the transmission line is 0.24 mm.

9. The low phase noise VCO of claim 5, wherein the width of the unit cell-pair and the width of the transmission line are all 5.525 mm.
